(19) United States
(12) Patent Application Publication
(10) Pub. No.: US 2023/0262979 A1
(43) Pub. Date: Aug. 17, 2023

(54) 3D AND FLASH MEMORY DEVICE AND METHOD OF FABRICATING THE SAME

(71) Applicant: MACRONIX International Co., Ltd., Hsinchu (TW)

(72) Inventor: Yan-Ru Su, Chiayi County (TW)

(73) Assignee: MACRONIX International Co., Ltd., Hsinchu (TW)

(21) Appl. No.: 17/674,645

(22) Filed: Feb. 17, 2022

(51) Int. Cl. H01L 27/11582

(52) U.S. Cl. CPC H01L 27/11582

(57) ABSTRACT

A memory device includes a dielectric substrate, a conductive layer, a gate stack structure, a plurality of ring-shaped slits and a plurality of inner slits. The conductive layer is located on the dielectric substrate. The gate stack structure is located on a first part of the conductive layer. The dielectric layer is located on the gate stack structure and a second part of the conductive layer. The plurality of ring-shaped slits extends through the dielectric layer, the gate stack structure and the conductive layer to define a plurality of tiles. The plurality of inner slits are arranged in the ring-shaped slits to define a plurality of blocks in each ring-shaped slit. A height of the plurality of inner slits is the same as a height of the plurality of ring-shaped slits.

### BACKGROUND

### Technical Field

The embodiment of the disclosure relates to a semiconductor device and a method of fabricating the same, and particularly, to a 3D AND flash memory device and a method of fabricating the same.

### Description of Related Art

Since a non-volatile memory has the advantage that stored data does not disappear at power-off, it becomes a widely used memory for a personal computer or other electronics equipment. Currently, the three-dimensional (3D) memory commonly used in the industry includes a NOR memory and a NAND memory. In addition, another type of 3D memory is an AND memory, which may be applied to a multi-dimensional memory array with high integration and high area utilization, and has an advantage of a fast operation speed. Therefore, the development of a 3D memory device has gradually become the current trend.

### SUMMARY

A memory device according to an embodiment of the disclosure includes a dielectric substrate, a conductive layer, a gate stack structure, a plurality of ring-shaped slits and a plurality of inner slits. The conductive layer is located on the dielectric substrate. The gate stack structure is located on a first part of the conductive layer. The dielectric layer is located on the gate stack structure and a second part of the conductive layer. The plurality of ring-shaped slits extends through the dielectric layer, the gate stack structure and the conductive layer to define a plurality of tiles. The plurality of inner slits are arranged in the ring-shaped slits to define a plurality of blocks in each ring-shaped slit. A height of the plurality of inner slits is the same as a height of the plurality of ring-shaped slits.

A gate stack structure on the blanket conductive layer. A plurality of channel openings are formed in the gate stack structure, wherein the plurality of channel openings expose the blanket conductive layer. A channel pillar is formed in each channel opening. A charge storage structure is formed between the channel pillar and a plurality of gate conductive layers of the gate stack structure. A dielectric layer is formed on the gate stack structure and the blanket conductive layer. A plurality of slit structures extends through the dielectric layer, the gate stack structure, and the blanket conductive layer to define a plurality of tiles, and to define a plurality of blocks in each tile.

A method for manufacturing a memory device according to an embodiment of the disclosure includes the following steps. A dielectric substrate is provided. A blanket conductive layer is formed to cover the dielectric substrate. A gate stack structure on the blanket conductive layer. A plurality of channel openings are formed in the gate stack structure, wherein the plurality of channel openings expose the blanket conductive layer. A channel pillar is formed in each channel opening. A charge storage structure is formed between the channel pillar and a plurality of gate conductive layers of the gate stack structure. A dielectric layer is formed on the gate stack structure and the blanket conductive layer. A plurality of slit structures extends through the dielectric layer, the gate stack structure, and the blanket conductive layer to define a plurality of tiles, and to define a plurality of blocks in each tile.

Based on the above, in the embodiment of the present disclosure, the conductive layer disposed below the stack structure is patterned while a slit structure is formed. Therefore, the conductive layer may be used as the conduction path of the charge during the dry etching (for example, plasma etching) process for forming the channel opening. As a result, the are effect may be reduced, and the damage of the various material layers and components on the substrate due to plasma bombardment may be avoided. Therefore, the yield of the process may be improved.

### BRIEF DESCRIPTION OF THE DRAWINGS

FIG. 1A shows a circuit diagram of a 3D AND flash memory array according to some embodiments in according to the present disclosure.

FIG. 1B shows a partial simplified perspective view of the memory array in FIG. 1A.

FIG. 1C and FIG. 1D show cross-sectional views taken along line I-I′ of FIG. 1B.

FIG. 1E shows atop view of line II-II′ of FIG. 1C and FIG. 1D.

FIG. 2A shows a top view of a memory chip in according to an embodiment of the present disclosure.

FIG. 2B shows a top view of a local region in FIG. 2A.

FIG. 3A to FIG. 3F show top views of the manufacturing process of the memory device in according to an embodiment of the present disclosure.

FIG. 4A to FIG. 4F show cross-sectional views of the manufacturing process of the memory device in according to an embodiment of the present disclosure.

FIG. 5A to FIG. 5C show schematic cross-sectional views of various slit structure in according to an embodiment of the present disclosure.

FIG. 6A to FIG. 6F show a perspective view and a cross-sectional view of each local region in FIG. 3F and FIG. 7B.

FIG. 7A shows a top view of a plurality of tiles of memory device in according to another embodiment of the present disclosure.

FIG. 7B shows a top view of a plurality of tiles of memory device in according to yet another embodiment of the present disclosure.

FIG. 8 shows a top view of another memory chip in according to yet an embodiment of the present disclosure.

### DESCRIPTION OF THE EMBODIMENTS

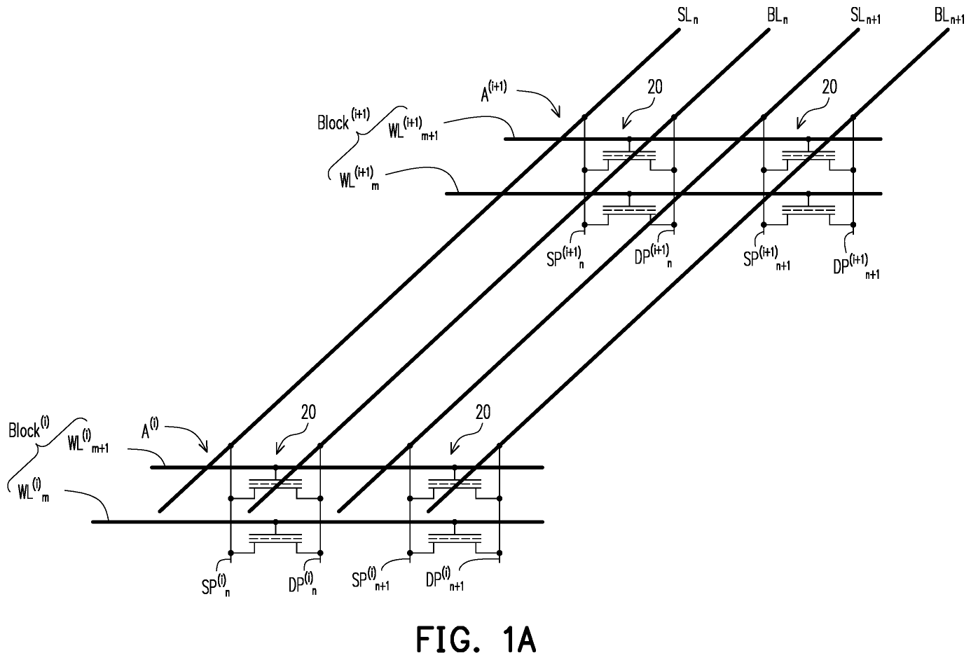

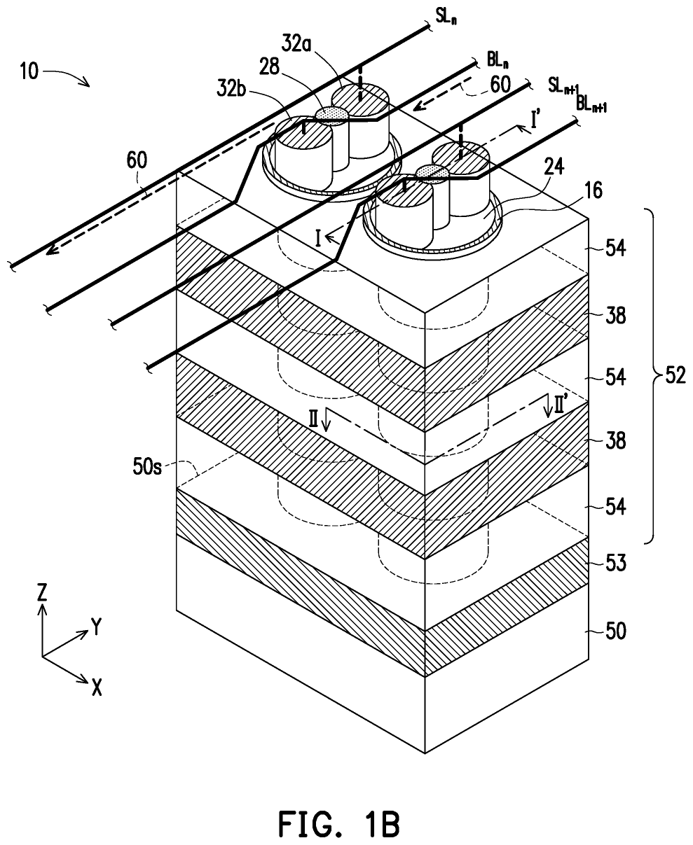

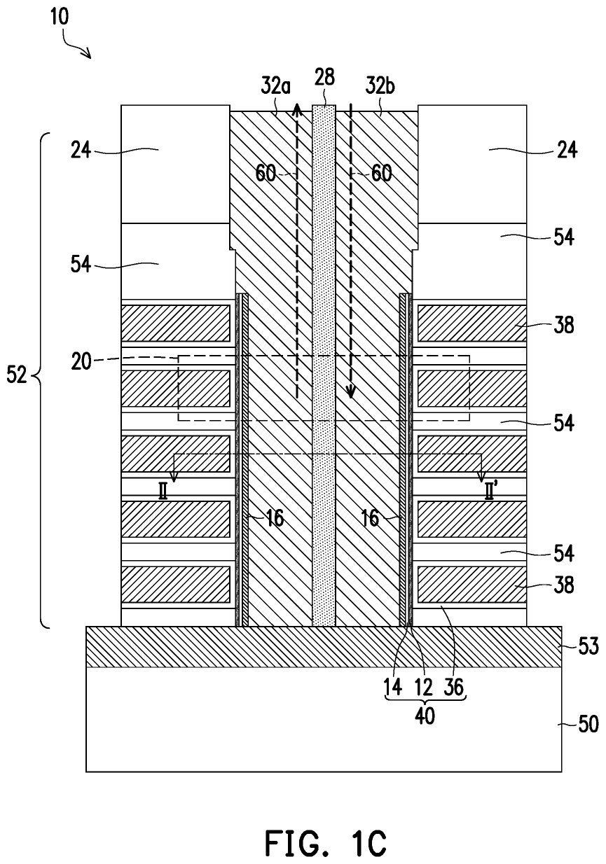

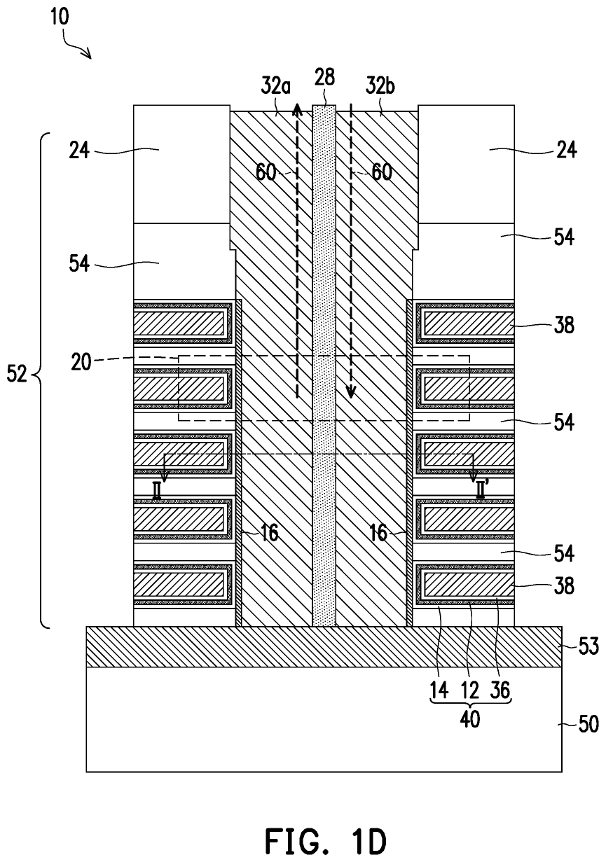

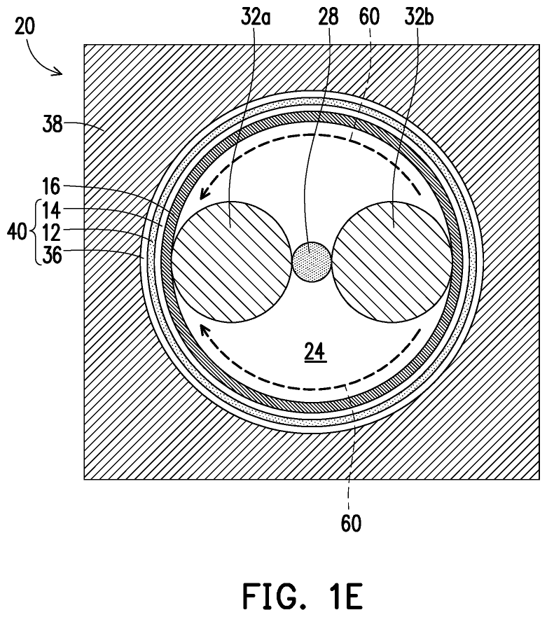

FIG. 1A shows a circuit diagram of a 3D AND flash memory array according to some embodiments in according to the present disclosure. FIG. 1B shows a partial simplified perspective view of the memory array in FIG. 1A. FIG. 1C and FIG. 1D show cross-sectional views taken along line I-I′ of FIG. 1B. FIG. 1E shows a top view of line II-II′ of FIG. 1C and FIG. 1D.

FIG. 1A shows a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)^{th} row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an n^{th} column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the n^{th} column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)^{th} column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)^{th} row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 of the memory array A⁽ⁱ⁺¹⁾ in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells 20 in the AND memory array A⁽ⁱ⁾ of the block BLOCK⁽ⁱ⁾, and are coupled to the n^{th} column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)^{th} column of AND memory cells 20 in the AND memory array A⁽ⁱ⁾ of the block BLOCK⁽ⁱ⁾, and are coupled to the (n+1)^{th} column of AND memory cells 20 in the AND memory array A⁽ⁱ⁺¹⁾ of the block BLOCK⁽ⁱ⁺¹⁾.

Referring to FIG. 1B and FIG. 1D, the memory array 10 may be disposed over an interconnect structure of a semiconductor die, for example, being disposed on one or more active devices (e.g., transistors) formed on a semiconductor substrate. Therefore, the dielectric substrate 50 is, for example, a dielectric layer (e.g., a silicon oxide layer) over a conductive interconnect structure formed on a silicon substrate. The memory array 10 may include a gate stack structure 52, a plurality of channel pillars 116, a plurality of first conductive pillars (also referred to as source pillars) 32a, a plurality of second conductive pillars (also referred to as drain pillars) 32b, and a plurality of charge storage structures 40.

Referring to FIG. 1B, the gate stack structure 52 is formed on the dielectric substrate 50 in the array region (not shown) and the staircase region (not shown). The gate stack structure 52 includes a plurality of gate layers (also referred to as word lines) 38 and a plurality of insulating layer 54 vertically stacked on a surface 50s of the dielectric substrate 50. In a direction Z, the gate layers 38 are electrically isolated from each other by the insulating layer 54 disposed therebetween. The gate layer 38 extends in a direction parallel to the surface 50s of the dielectric substrate 50. The gate layers 38 in the staircase region may have a staircase structure (not shown). Therefore, a lower gate layer 38 is longer than an upper gate layer 38, and the end of the lower gate layer 38 extends laterally beyond the end of the upper gate layer 38. A contact (not shown) for connecting the gate layer 38 may land on the end of the gate layer 38 to connect the gate layers 38 respectively to conductive lines.

Referring to FIG. 1B to FIG. 1D, the memory array 10 further includes a plurality of channel pillars 16 of the. The channel pillar 16 continuously extends through the gate stack structure 52 and a conductive layer 53 between the dielectric substrate 50 and the gate stack structure 52. The conductive layer 53 may include doped polysilicon such as P-type doped polysilicon. In some embodiments, the channel pillar 16 may have a ring shape in a top view. The material of the channel pillar 16 may be semiconductor such as undoped polysilicon.

Referring to FIG. 1B to FIG. 1D, the memory array 10 further includes an insulating pillar 28, a plurality of first conductive pillars 32a, and a plurality of second conductive pillars 32b. In this example, the first conductive pillars 32a serve as source pillars. The second conductive pillars 32b serve as drain pillars. The first conductive pillar 32a, the second conductive pillar 32b and the insulating pillar 28 are each extend in a direction (i.e., the direction Z) perpendicular to the gate layer 38. The first conductive pillar 32a and the second conductive pillar 32b are separated from each other by the insulating pillar 28, and around by an insulating filling layer 24. The first conductive pillar 32a and the second conductive pillar 32b are electrically connected to the channel pillar 16. The first conductive pillar 32a and the second conductive pillar 32b include doped polysilicon or metal materials. The insulating pillar 28 is, for example, silicon nitride or silicon oxide and the insulating filling layer 24 is, for example, silicon oxide.

Referring to FIG. 1C and FIG. 1D, at least a portion of the charge storage structure 40 is disposed between the channel pillar 16 and the gate layers 38. The charge storage structure 40 may include a tunneling layer (or referred to as a bandgap engineered tunneling oxide layer) 14, a charge storage layer 12, and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride or other materials capable of trapping charges. In some embodiments, as shown in FIG. 1C, a portion (the tunneling layer 14 and the charge storage layer 12) of the charge storage structure 40 continuously extends in a direction (i.e., the direction Z) perpendicular to the gate layer 38, and the other portion (the blocking layer 36) of the charge storage structure 40 surrounds the gate layer 38. In other embodiments, as shown in FIG. 1D, the charge storage structure 40 (the tunneling layer 14, the charge storage layer 12, and the blocking layer 36) surrounds the gate layer 38.

Referring to FIG. 1E, the charge storage structure 40, the channel pillar 16, the source pillar 32a, and the drain pillar 32b are surrounded by the gate layer 38, and a memory cell 20 is defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the channel pillar 16, electrons may be transferred along the channel pillar 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

During operation, a voltage is applied to a selected word line (gate layer) 38; for example, when a voltage higher than a corresponding threshold voltage (Vth) of the corresponding memory cell 20 is applied, a channel region of the channel pillar 16 intersecting the selected word line 38 is turned on to allow a current to enter the drain pillar 32b from the bit line BLₙ or BLₙ₊₁ (shown in FIG. 1B), flow to the source pillar 32a via the turned-on channel region (e.g., in a direction indicated by arrow 60), and finally flow to the source line SLₙ or SLₙ₊₁ (shown in FIG. 1B).

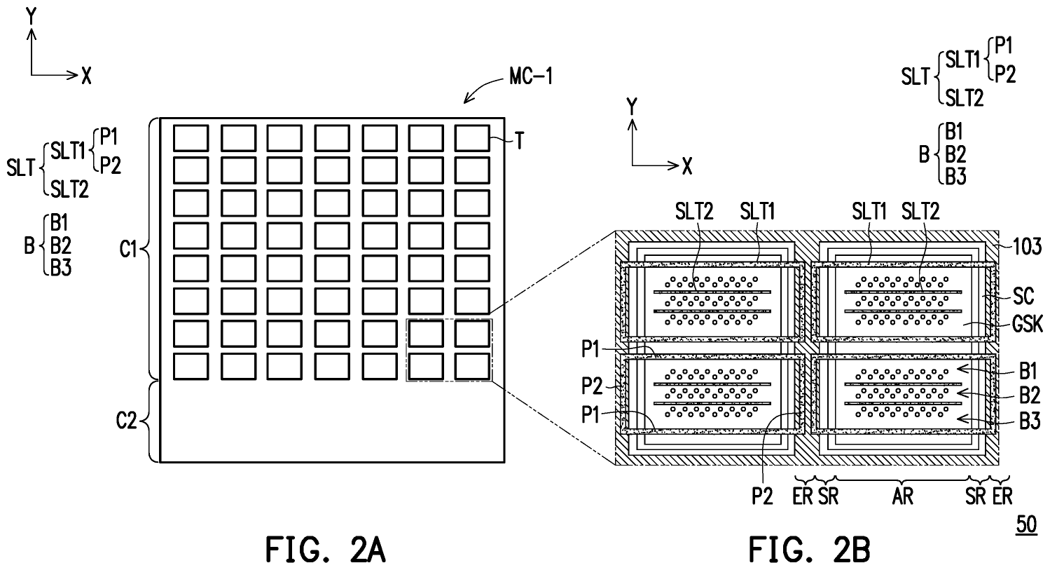

FIG. 2A shows a top view of a memory chip in according to an embodiment of the present disclosure. FIG. 2B shows a top view of a local region in FIG. 2A.

Referring to FIG. 2A and FIG. 213, the memory chip MC-1 is, for example, an AND memory device. The memory chip MC-1 may include a region C1 and a region C2. The region C1 may include a plurality of tiles T separated from each other. The tile T may be arranged into an array with multiple rows and multiple columns. In FIG. 2A, the tile array is formed by seven columns and eight rows, however, the embodiment of the present invention is not limited thereto. Each tile T in the region C1 has multiple memory arrays. The region C2 includes peripheral circuits, for example, a complementary metal oxide semiconductor device (CMOS) arranged on the periphery of the tile array.

Referring to FIG. 2A and FIG. 2B, the memory chip MC-1 also includes multiple sets of slit structures SLTs. Each set of slit structure SLT includes a first slit SLT1 and multiple second slits SLT2.

The first slit SLT1 surrounds the periphery of the plurality of second slits SLT2, and the second slits SLT2 are formed within the first slit SLT1. Therefore, the first slit SLT1 may also be referred to as an outer slit SLT1, and the second slits SLT2 may also be referred to as inner slits. The top view of the first slit SLT1 may be a ring, therefore, the first slit SLT1 may also be referred to as a ring slit. The second slit SLT2 is a strip extending in the X direction, so the second slit SLT2 may also be referred to as a strip slit.

The first slits SLT1 define a plurality of tiles T separated from each other. Each tile T may include an array region AR, a staircase region SR, and an edge region ER. The staircase region SR is around the array region AR. The edge region ER is around the staircase region SR. The memory array is formed in the array region AR. The first slits SLT1 are formed to separate two tiles T from each other. A plurality of slits SLT2 are arranged in the tile T, and each tile T defines a plurality of block B. FIG. 2B includes three blocks B1, B2, and B3. However, the embodiment of the present invention is not limited thereto.

The first slit SLT1 includes two first slit parts P1 and two second slit parts P2 connected to each other at the ends. Each first slit part P1 extends in the direction X and formed from the array region AR to the staircase region SR and the edge region ER. Each second slit parts P2 extend in the direction Y and formed in the edge region ER. In some embodiments, the direction X is referred to as a first direction, the direction Y is referred to as a second direction, and the direction X is referred to as a third direction.

Referring to FIG. 2B, the first slits SLT1 are separated from each other, and may be arranged into an array of multiple rows and multiple columns to define a tile array composed of multiple tiles.

Referring to FIG. 2B, in the embodiment of the present disclosure, the conductive layer 10 under the gate stack structure GSK remain unpatterned and blanketly covers the dielectric substrate 50 before forming the slit structure SLT. The conductive layer 53 may be used as a discharge path in the etching process for forming the channel opening. Therefore, the 3D memory device of the embodiment of the present disclosure does not require an additional discharge circuit which is formed in the interconnection structure under the gate stack structure GSK

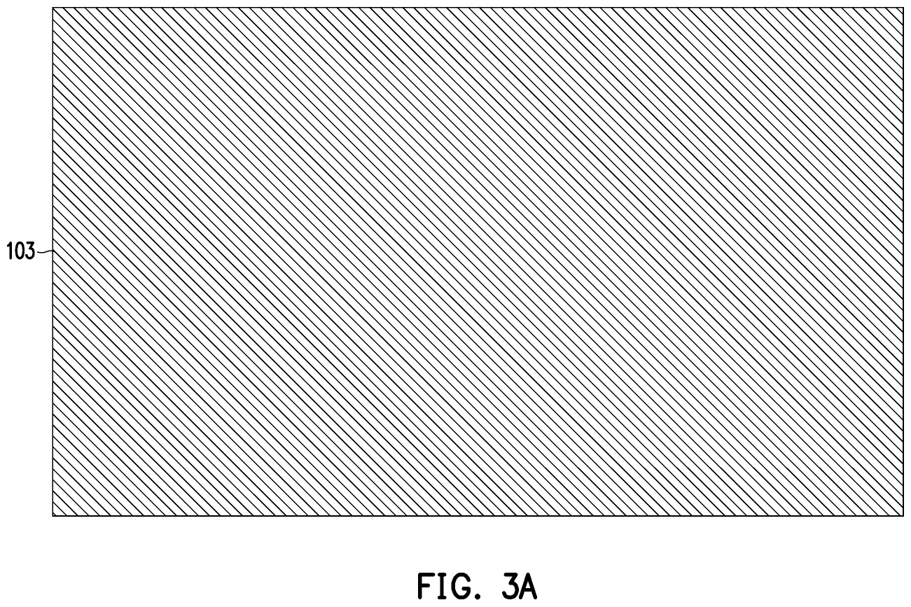

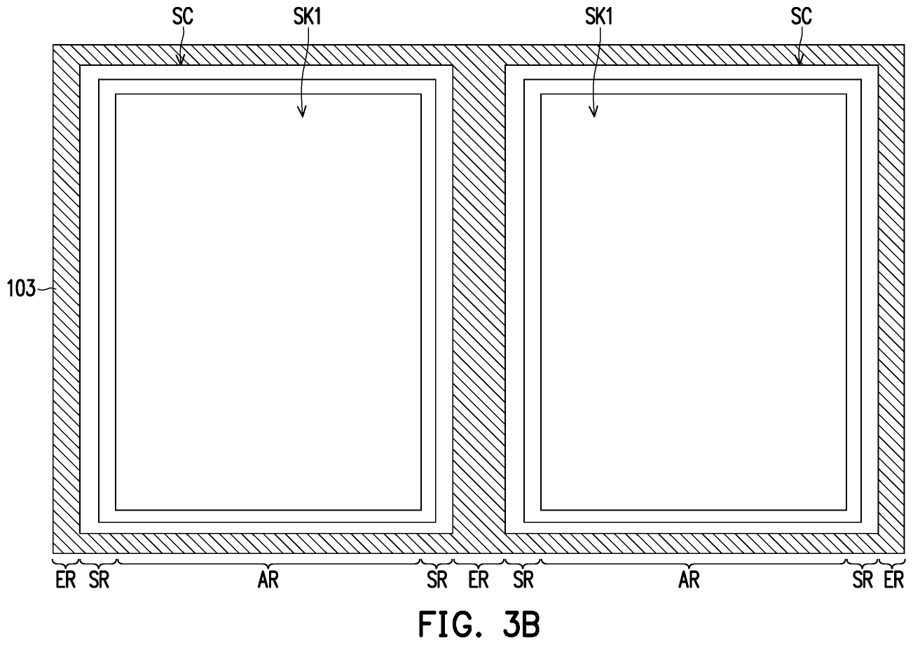

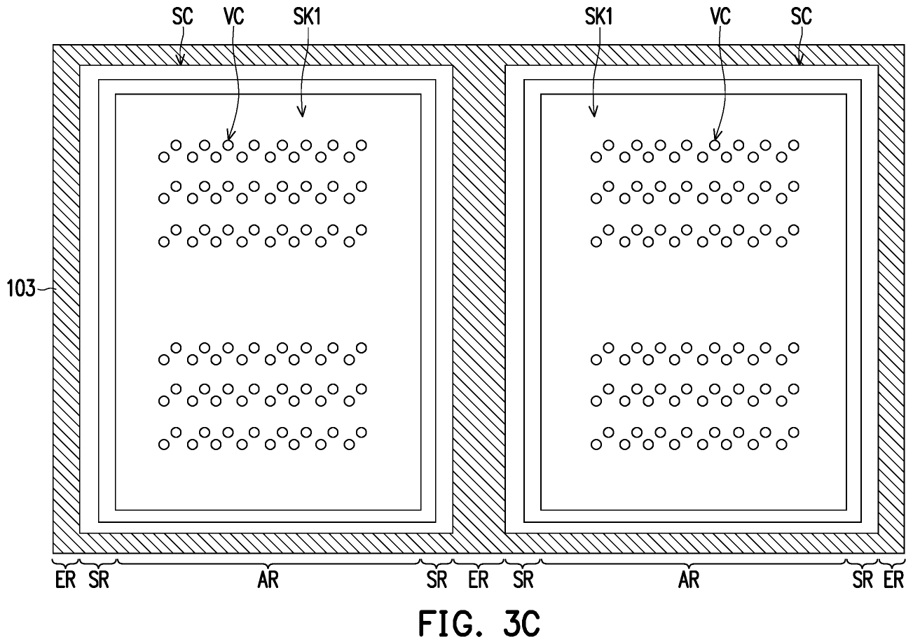

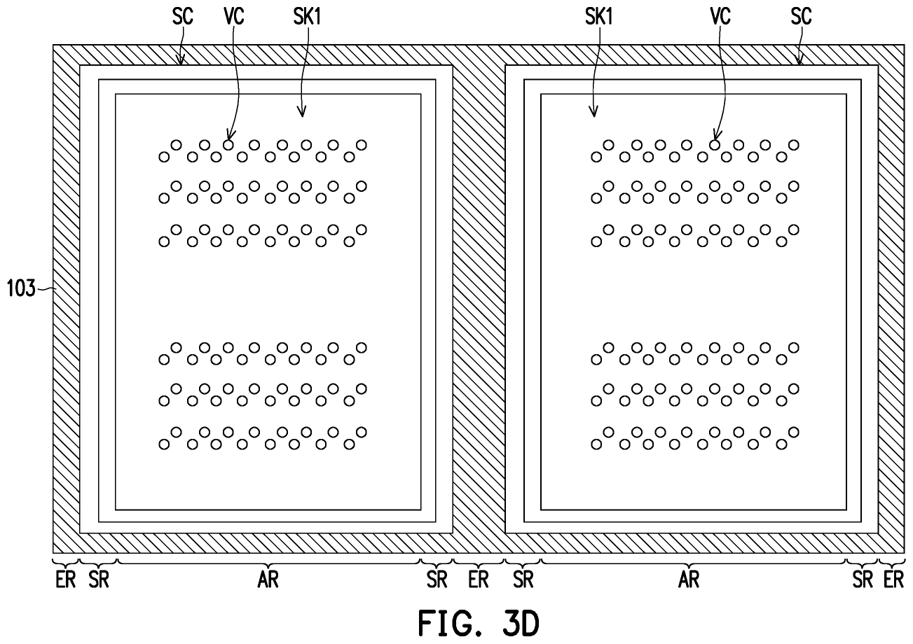

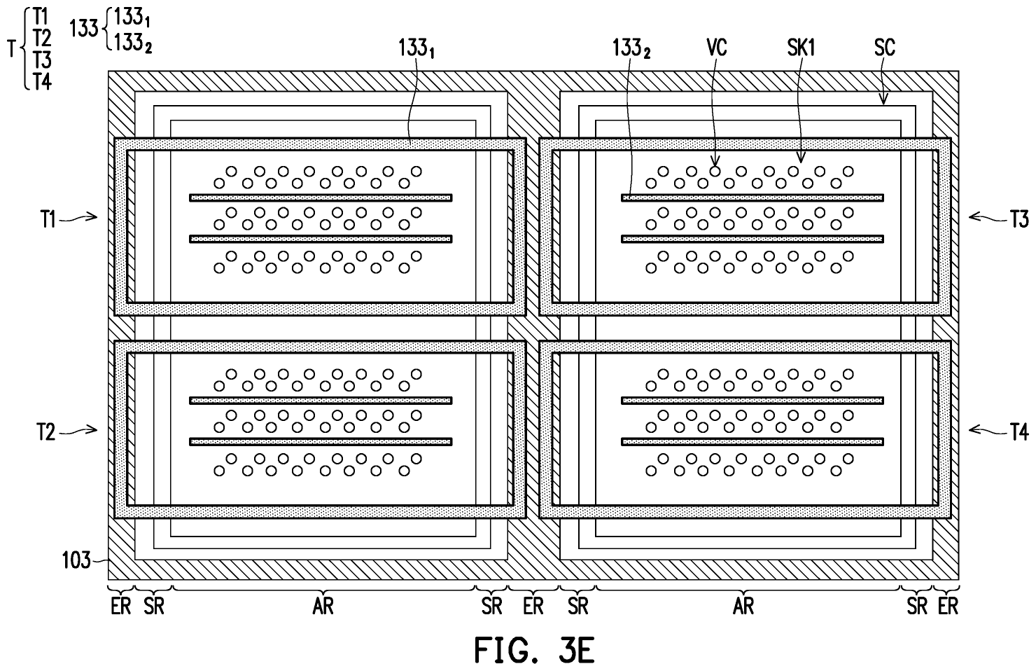

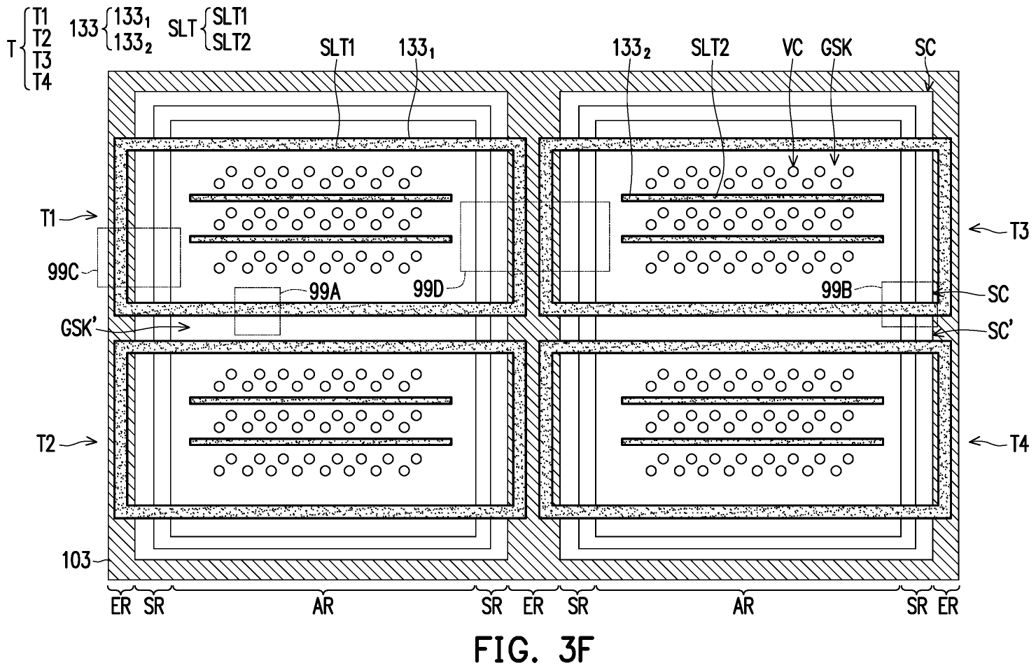

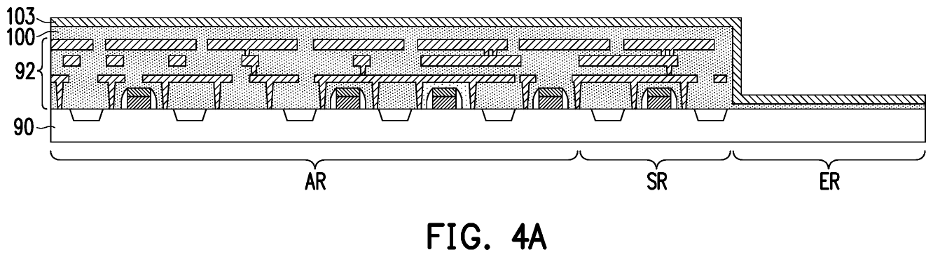

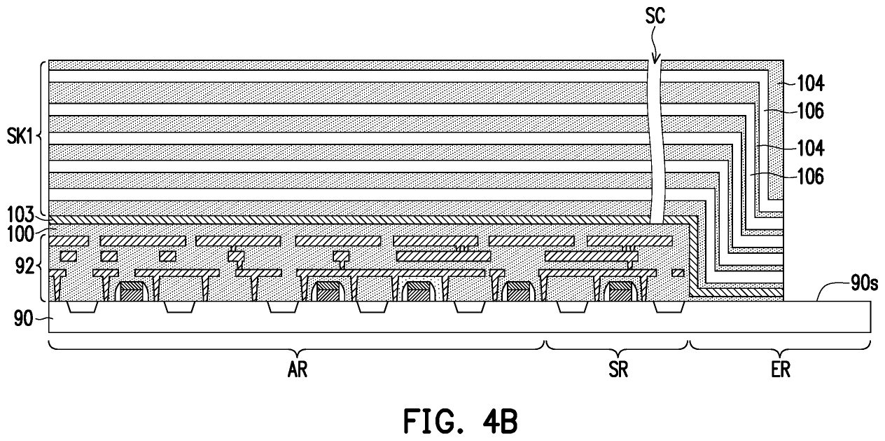

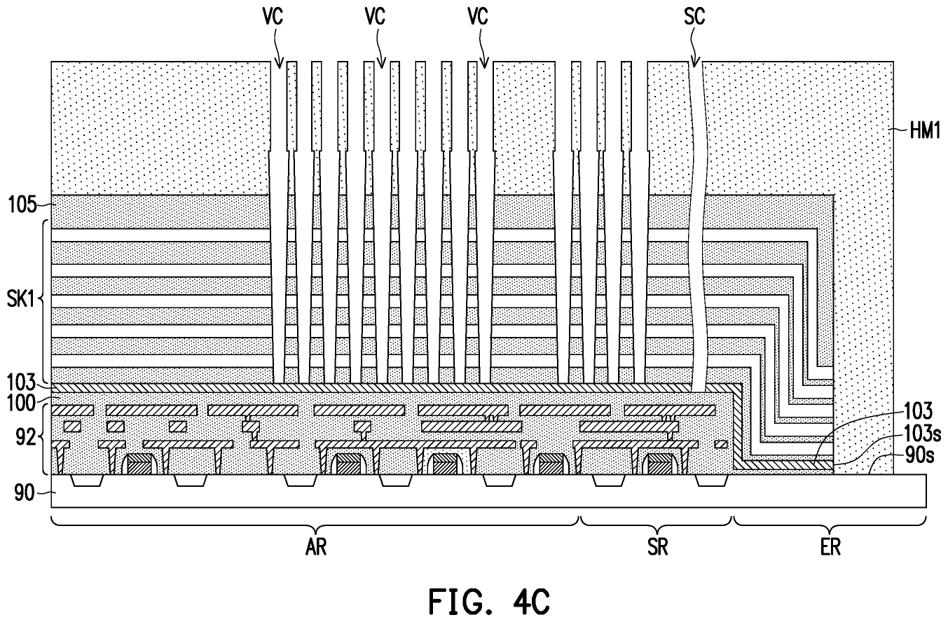

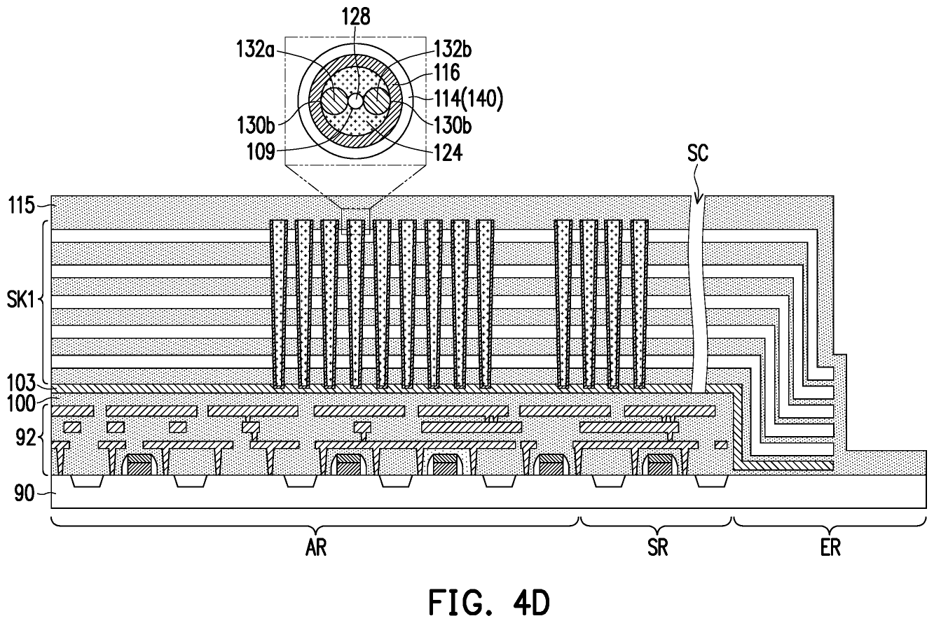

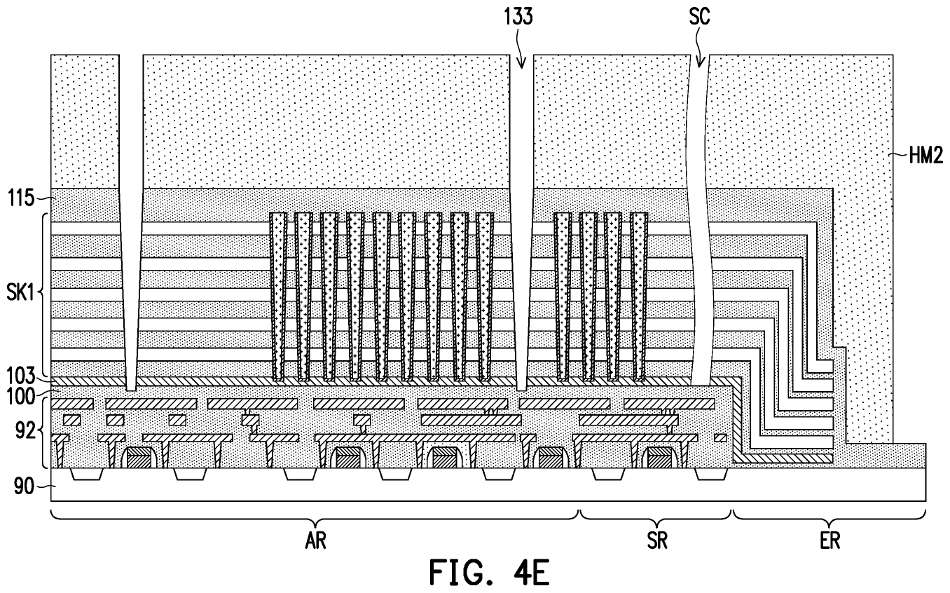

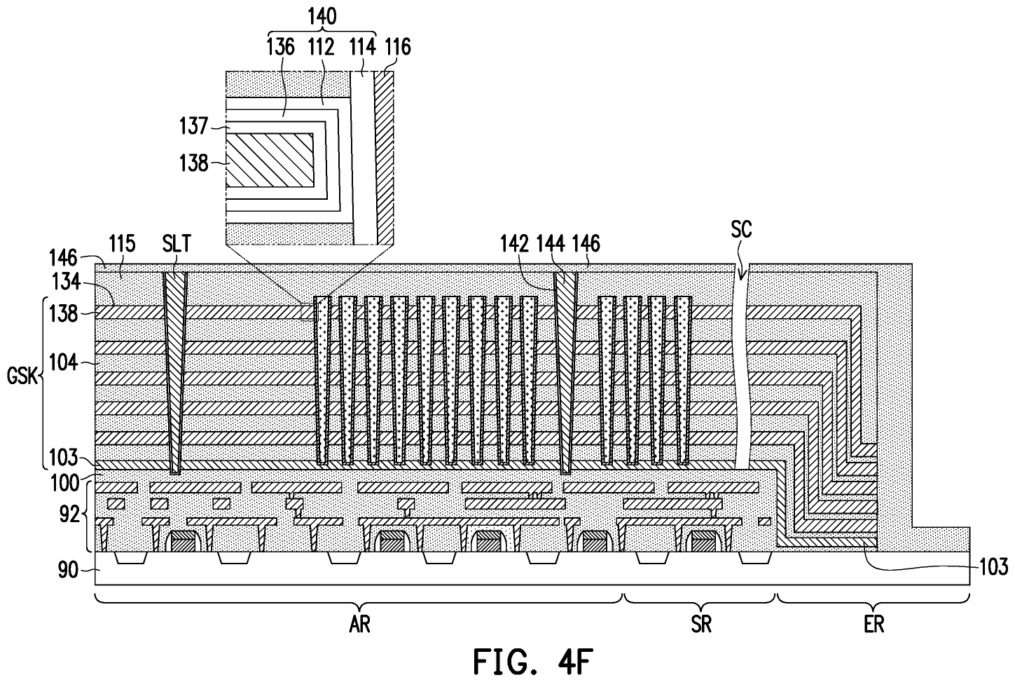

FIG. 3A to FIG. 3F show top views of the manufacturing process of the memory device in according to an embodiment of the present disclosure. FIG. 4A to FIG. 4F show cross-sectional views of the manufacturing process of the memory device in according to an embodiment of the present disclosure.

Referring to FIG. 3A and FIG. 4A, a substrate 90 is provided. The substrate 90 may include an array region AR, a staircase region SR, and an edge region ER. The substrate 90 may include a semiconductor substrate, such as a silicon substrate. The substrate 90 may include components formed on the semiconductor substrate such an active device (e.g., a PMOS, an NMOS, a CMOS, a JFET, a BJT, or a diode) or a passive device. An interconnect structure 92 is formed on the substrate 90 in the array region AR and the staircase region SR. The interconnect structure 92 may include components such as an inner dielectric layer, contacts, conductive lines, an interlayer dielectric layers, and vias. The inner dielectric layer and the interlayer dielectric layer are, for example, a silicon oxide. Next, a dielectric layer 100 is formed on the interconnect structure 92. The dielectric layer 100 is, for example, a silicon oxide. In some embodiments, the dielectric layer 100 may also be referred to as a dielectric substrate 100.

Next, referring to FIG. 3A and FIG. 4A, a conductive layer 103 is blanketly formed on the dielectric layer 100 in the array region AR and the staircase region SR. The conductive layer 103 also extends to the edge region ER. The conductive layer 103 is, for example, a grounded P-type doped polysilicon layer. The conductive layer 103 may also be referred to as a dummy gate, which may be used to close a leakage path.

Referring to FIG. 3B and FIG. 4B, A stack structure SK1 is formed on the conductive layer 103. The stack structure SK1 may also be referred to as an insulating stack structure SK1. In this embodiment, the stack structure SK1 is composed of insulating layers 104 and intermediate layers 106 that are sequentially alternately stacked on the conductive layer 103. In other embodiments, the stack structure SK1 may be composed of intermediate layers 106 and insulating layers 104 that are sequentially alternately stacked on the conductive layer 103. In addition, in this embodiment, the uppermost layer of the stack structure SK1 is the insulating layer 104. The material of the insulating layer 104 is, for example, a silicon oxide. The material of the intermediate layer 106 is, for example, a silicon nitride. The intermediate layer 106 may serve as a sacrificial layer which may be partially removed in the subsequent process. In this embodiment, the stack structure SK1 has five insulating layers 104 and four intermediate layers 106, but the disclosure is not limited thereto. In other embodiments, more insulating layers 104 and more intermediate layers 106 may be formed according to the actual requirements.

Referring to FIG. 3B, the stack structure SK1 is patterned to form a staircase structure SC in the staircase region SR, and a portion of the stack structure SK1 in the edge region ER is removed to expose the surface 90s of the substrate 90. For simplicity, the staircase structure SC is not shown in FIG. 4B.

FIG. 3C and FIG. 4C, a dielectric layer 105 is formed on the substrate 90 to cover the staircase structure SC. The dielectric layer 105 is silicon oxide, for example. The formation method of the dielectric layer 105 is, for example, forming a dielectric material layer to fill and cover the staircase structure SC. Afterwards, a planarization process is performed by, for example, a chemical mechanical polishing process.

After that, a hard mask layer HM1 is formed on the dielectric layer 105. The hard mask layer HM1 is, for example, a carbon-containing layer. The hard mask layer HM1 covers the array region AR, the staircase region SR, and the edge region ER, and is electrically connected to the surface 90s of the substrate 90 in the edge region ER and the sidewalls 103s of the conductive layer 103. That is, the conductive layer 103 may be electrically connected to the substrate 90 via the hard mask layer HM1.

A patterning process (e.g., photolithography and etching processes) is performed on the hard mask layer HM1. Then, the hard mask layer HM1 is used as a mask to perform an etching process to form multiple holes VC in the stack structure SK1. The opening VC exposes the conductive layer 103. The etch process may be a dry etch process, a wet etch process, or a combination thereof. For example, dry etch process is plasma etch process. Since the conductive layer 103 blanketly overlies the substrate 90, the conductive layer 103 may be used as the conduction path for the charge during the plasma etching process to pass the charge to the substrate 90 via the hard mask layer HM1. Therefore, the are effect may be reduced, and various material layers and components on the substrate 90 can be prevented from being damaged by plasma bombardment.

In this embodiment, the opening VC does not extend through the conductive layer 103. In this embodiment, in a top view, the opening VC has a circular profile, but the disclosure is not limited thereto. In other embodiments, the opening VC may have a profile of other shapes such as a polygonal shape (not shown).

FIG. 3D and FIG. 4D, the hard mask layer HM1 is removed. A tunneling material and a channel material of the charge storage structure 140 are formed in the opening VC. Then, an etch-back process is performed to partially remove the channel material and the tunneling material to form the channel pillar 116 and the tunneling layer 114.

The tunneling layer 114 and the channel pillar 116 extend through the stack structure SK1 and do not extend through the conductive layer 103 but are not limited thereto. In a top view, the channel pillar 116 has, for example, a ring shape, and the channel pillar 116 may be continuous in its extending direction (e.g., in a direction perpendicular to the dielectric substrate 100). In other words, the channel pillar 116 is integral in its extending direction and is not divided into multiple disconnected parts. In some embodiments, the channel pillar 116 may have a circular profile in a top view, but the disclosure is not limited thereto. In other embodiments, the channel pillar 116 may also have a profile of other shapes (e.g., a polygonal shape) in a top view.

An insulating filling material is formed on the stack structure SK1 and filled in the opening VC. The insulating filling material is, for example, a low-temperature silicon oxide. The insulating filling material filled in the opening VC forms an insulating filling layer 124, and a circular seam is left at the center of the insulating filling layer 124. Then, an anisotropic etching process is performed to expand the circular seam to form a hole 109. An insulating material layer is formed on the insulating filling layer 124 and in the hole 109. Then, an anisotropic etching process is performed to remove part of the insulating material layer to form an insulating pillar 128 in the hole 109. The material of the insulating pillar 128 is different from the material of the insulating filling layer 124. The material of the insulating pillar 128 is, for example, silicon nitride.

FIG. 3E and FIG. 4E, a patterning process (e.g., photolithography and etching processes) is performed to form holes 130a and 130b in the insulating filling layer 124. In the etching process, the conductive layer 103 may serve as an etch stop layer. Therefore, the formed holes 130a and 130b extend from the stack structure SK1 until the conductive layer 103 is exposed. The profiles of the hole patterns defined in the patterning process may be tangent to the profile of the insulating pillar 128. The profiles of the hole patterns defined in the patterning process may also exceed the profile of the insulating pillar 128 (not shown).

Then, a capping insulating layer 115 is formed on the stack structure SK1. The material of the capping insulating layer 115 is, for example, a silicon oxide.

Referring to FIG. 3E and FIG. 4E, a wafer bevel engineering process is performed to remove part of the capping insulating layer 115 in the edge region ER to expose the surface 90s of the substrate 90. A hard mask layer HM2 is then formed on the capping insulating layer 115. The hard mask layer HM2 is, for example, a carbon-containing layer. The hard mask layer HM2 covers the capping insulating layer 115 in the array region AR, the staircase region SC, and the edge region ER, and is electrically connected to the surface 90s of the substrate 90 and the sidewalls 103s of the conductive layer 103 in the edge region ER.

A patterning process (e.g., photolithography and etching processes) is performed on the hard mask layer HM2. Then, the hard mask layer HM2 is used as a mask to perform an etching process to pattern the stack structure SK1 and the conductive layer 103 to form multiple slit trenches 133. During the etching process, the dielectric layer 100 or the conductive layer 103 may be used as the etch stop layer, so that the slit trench 133 exposes the dielectric layer 100 or the conductive layer 103. The etching process may be a dry etch process, such as a plasma etching process. Since the hard mask layer HM2 is a carbon-containing layer, the conductive layer 103 may be used as the conduction path for the charge during the plasma etching process to pass the charge to the substrate 90 via the hard mask layer HM2. Therefore, the are effect may be reduced and various material layers and components on the substrate 90 can be prevented from being damaged by plasma bombardment.

Each slit trench 133 includes a first slit trench 133₁ and a plurality of second slit trenches 133₂. The first slit trench 133₁ surround the periphery of the plurality of second slit trenches 133₂, and the plurality of second slit trenches 133₂ are inside the first slit trench 133₁. Therefore, the first slit trench 133₁ may also be referred to as an outer slit trench, and the second slit trench 133₂ may also be referred to as an inner slit trench. The first slit trench 133₁ may be an ring-shaped slit trench. The first slit trench 133₁ patterns the stack structure SK1 and the conductive layer 103 into a plurality of tiles T (for example, T1, T2, T2, T4). The second slit trenches 133₂ divide each tile T into multiple block B (for example, B1, B2, B3).

Referring to FIG. 3F and FIG. 4F, the hard mask layer HM2 is removed. Afterwards, a replacement process is performed on the intermediate layers 106. First, an etching process such as a wet etching process is performed to remove part of the intermediate layers 106. An etching solution (e.g., hot phosphoric acid) used in the etching process is injected into the slit trenches 133, and then the contacted portion of the intermediate layers 106 is removed to form a plurality of horizontal openings 134.

A plurality of charge storage layers 112, a plurality of blocking layers 136, and a plurality of gate layers 138 are formed in the horizontal openings 134. The material of the charge storage layer 112 is, for example, silicon nitride. The material of the blocking layer 136 is, for example, a high dielectric constant material having a dielectric constant greater than or equal to 7, such as aluminum oxide (Al₁O₃), hafnium oxide (HfO₂), lanthanum oxide (La₂O₅), transition metal oxide, lanthanide oxide, or combinations thereof. The material of the gate layer 138 is, for example, tungsten. In some embodiments, before the gate layers 138 are formed, a barrier layers 137 is formed. The material of the barrier layer 137 is, for example, titanium (Ti), titanium nitride (TiN), tantalum (Ta), tantalum nitride (TaN), or a combination thereof.

The method of forming the charge storage layer 112, the blocking layer 136, the barrier layer 137, and the gate layer 138 includes, for example, sequentially forming a storage material, a blocking material, a barrier material, and a conductive material in the slit trench 133 and the horizontal opening 134. Then, an etch-back process is performed to remove the storage material, the blocking material, the barrier material, and the conductive material in the slit trenches 133 to form the charge storage layer 112, the blocking layer 136, the barrier layer 137, and the gate layer 138 in the horizontal openings 134. The tunneling layer 114, the charge storage layer 112, and the blocking layer 136 are collectively referred to as a charge storage structure 140. At this time, a gate stack structure 150 is formed. The gate stack structure GSK is disposed on the dielectric substrate 100 and includes a plurality of gate layers 138 and a plurality of insulating layers 104 stacked alternately with each other.

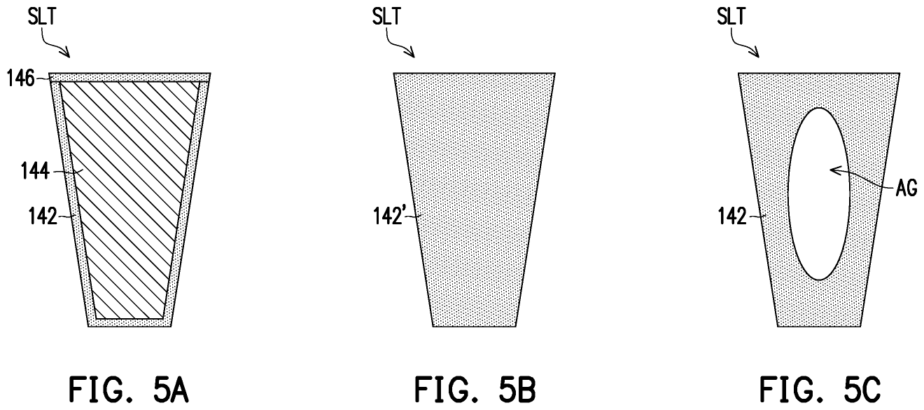

Referring to FIG. 3F and FIG. 4F, slit structures SLT are formed in the slit trenches 133. That is, the first slits SLT1 are formed in the first slit trenches 133₁, and the second slits SLT2 are formed in the second slit trenches 133₂. The first slits SLT1 and the second slits SLT2 have the same height. The height of The first slits SLT1 and the second slits SLT2 is greater than the height of the conductive layer 103 and greater than the height of the gate stack structure GSK. The slit structure SLT may be a single layer or multiple layers, as shown in FIG. 5A to FIG. 5C.

Referring to FIG. 3F, FIG. 4F and FIG. 5A, the formation method of the slit structure SLT includes the following steps. An insulating liner and a conductive material is formed on the gate stack structure GSK and fill in the slit trenches 133. The insulating liner is, for example, silicon oxide. The conductive material is, for example, polysilicon. Then, the excess insulating liner and conductive material on the gate stack structure GSK and in edge region ER are removed through an etching process or a planarization process to form the liner layer 142 and the conductive layer 144. A dielectric material is formed over the substrate 90, and then the dielectric material is planarized through an etching process or a planarization process to form a dielectric layer 146. The liner layer 142, the conductive layer 144 and the dielectric layer 146 form the slit structure SLT, as shown in FIG. 5A.

In some embodiments, the slit structure SLT can also be completely filled with an insulating material 142′ without any conductive material, as shown in FIG. 5B. In other some embodiments, the slit structure SLT may also be a liner layer 142, and an air gap (air gap) AG is covered with the liner layer 142 without any conductive material, as shown in FIG. 5C.

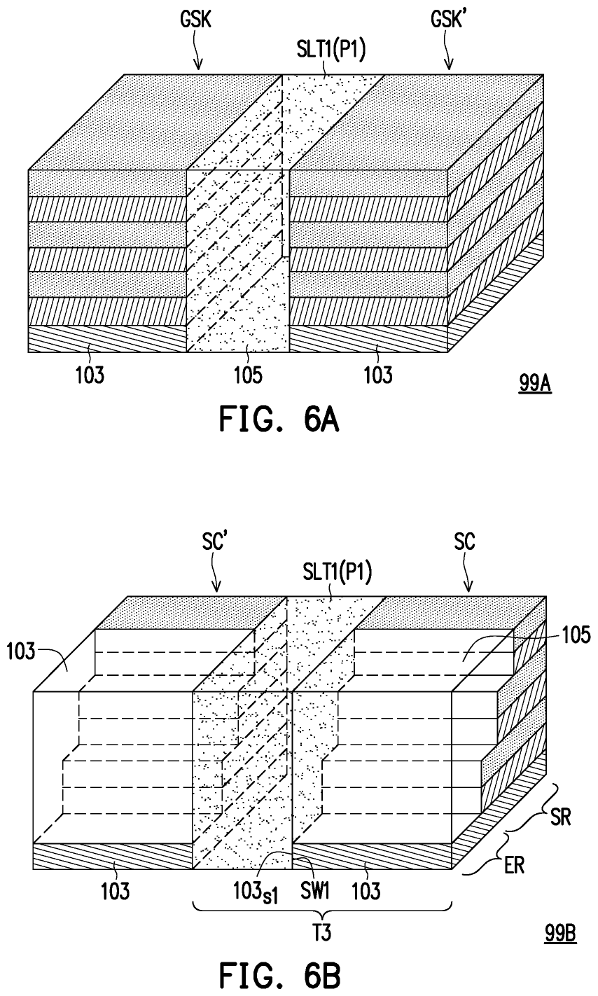

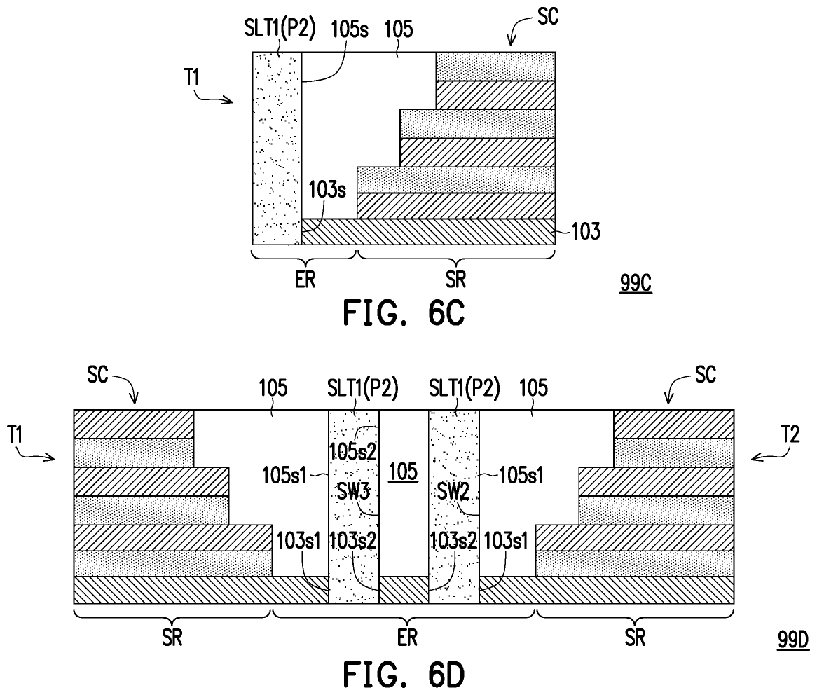

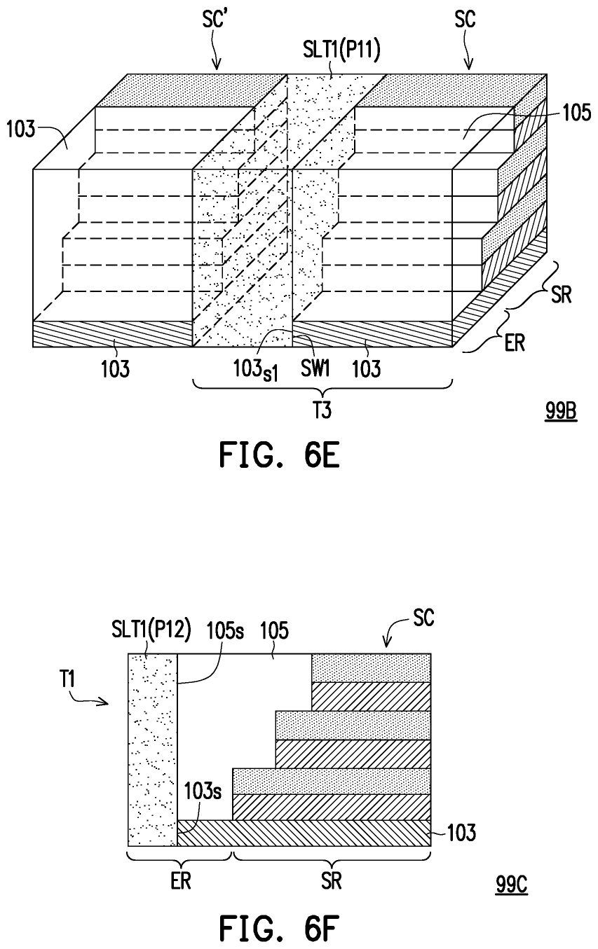

FIG. 6A to FIG. 6D show a perspective view and a cross-sectional view of regions 99A, 99B, 99C and 99D in FIG. 3F.

Referring to FIG. 3F and FIG. 6A, in the region 99A of FIG. 3F, the first slit part P1 of the first slit SLT1 divides the gate stack structure GSK of the tile T1 and the gate stack structure GSK′ located between the tile T1 and the tile T2. The edges of conductive layer 103 are aligned with the edge of the gate stack structure GSK and the edge of the gate stack structure GSK′.

Referring to FIG. 3F and FIG. 6B, in the region 99B of FIG. 3F, the first slit part P1 of the first slit SLT1 separates the staircase structures SC of the tile T3 and the staircase structures SC′ located between the tile T3 and the tile T4. The conductive layer 103 extends from the staircase region SR to the edge region ER. The surface 103S1 of first parts of the conductive layer 103 in the staircase region SR are covered by the staircase structure SC of the tile 3 and the staircase structure SC′ between the tile T3 and the tile T4, and the staircase structures SC and SC′ is covered by the dielectric layer 105. The surface 103S2 of second parts of the conductive layer 103 in the edge region ER are covered by the dielectric layer 105. The sidewalls 103s1 of conductive layer 103 are in contact with the sidewalls SW1 of the first slit part P1 of the first slit SLT1.

Referring to FIG. 3F and FIG. 6C, in the region 99C of FIG. 3F, the second slit part P2 of the first slit SLT1 is located in the edge region ER of the tile T1. In addition, the sidewalls of the second slit part P2 of the first slit SLT1 is in contact with the sidewalls 103s of the conductive layer 103 and the sidewalls 105s of the dielectric layer 105 which covers on the staircase structure SC and the conductive layer 103.

Referring to FIG. 3F and FIG. 6D, in the 99D of FIG. 3F, there are two second slit parts P2 between adjacent tiles T1 and T3. The two second slit parts P2 of the first slit SLT1 extends through the dielectric layer 105 and the conductive layer 103 in the edge region ER. In addition, the outer sidewalls SW2 of the second slit parts P2 of the first slits SLT1 are in contact with the sidewalls 103s1 of the conductive layer 103 and the sidewalls 105s1 of the dielectric layer 105 which cover the staircase structure SC and the conductive layer 103. The inner sidewalls SW3 of the second slit parts P2 of the first slits SLT1 are in contact with the sidewalls 103s2 of the conductive layer 103 and the sidewalls 105s2 of the dielectric layer 105 which covers the conductive layer 103.

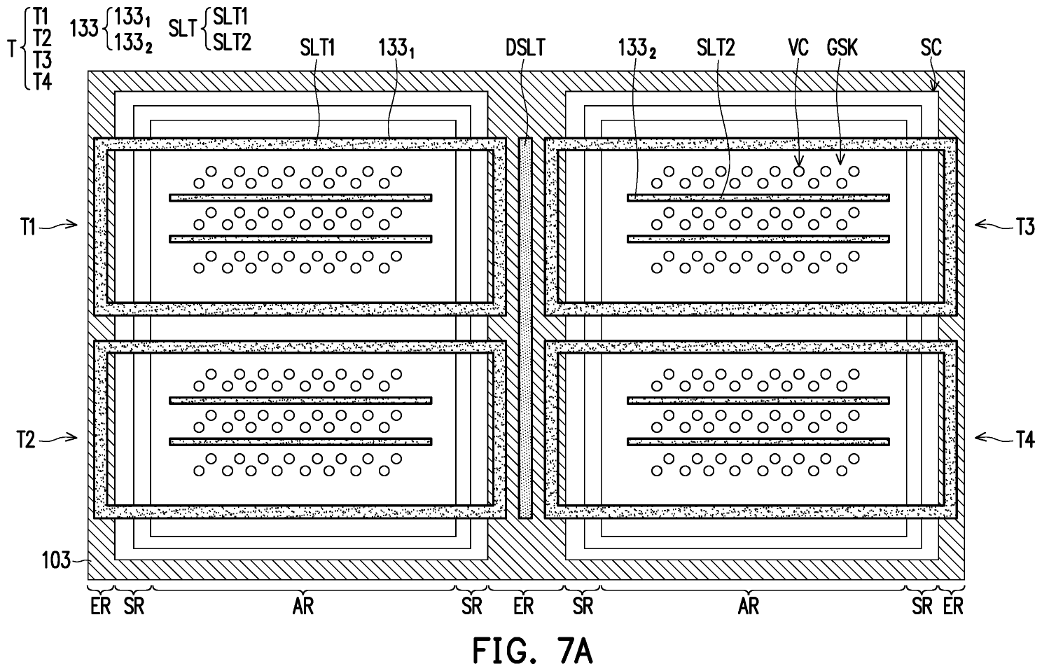

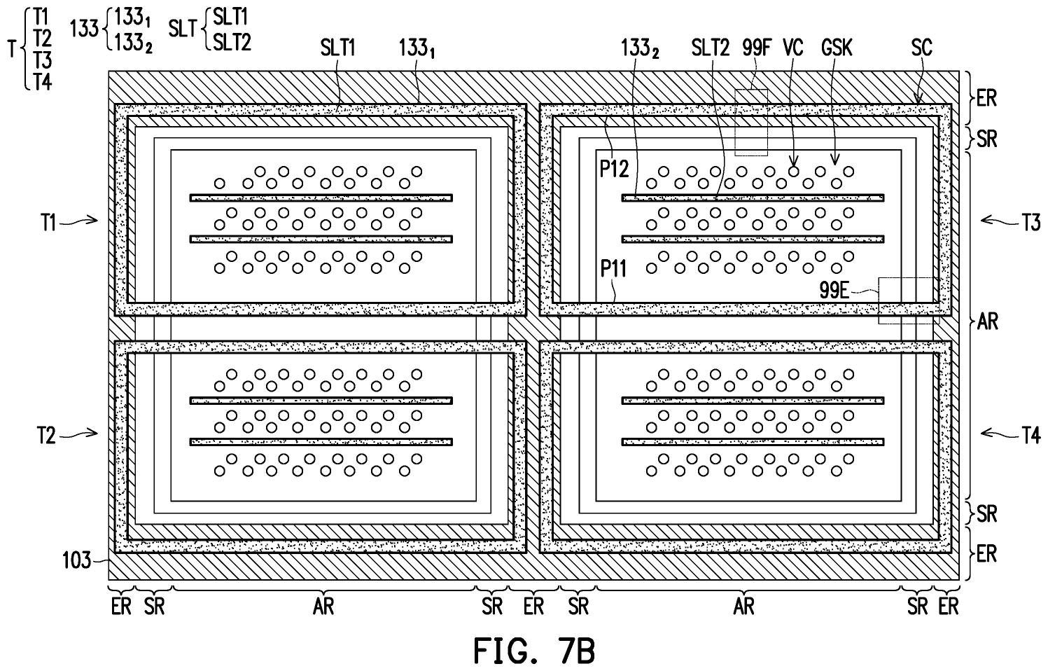

FIG. 7A shows a top view of a plurality of tiles of memory device in according to another embodiment of the present disclosure. FIG. 7B shows atop view of a plurality of tiles of memory device in according to yet another embodiment of the present disclosure. FIG. 6E to FIG. 6F show a perspective view and a cross-sectional view of regions 99E and 99F in FIG. 7B.

Referring to FIG. 7A, in some embodiments, at least one dummy slit DSLT may also be included between two adjacent tiles T1 and T3 and between tiles T2 and T4. The least one dummy slit DSLT is formed between two adjacent second slit parts P2. The least one dummy slit DSLT and the second slit parts P2 may be formed at the same time.

Referring to FIG. 7B, in some embodiments, a first slit part P11 of the first slits SLT1 passes through the gate stack structure GSK, the staircase structure SC, the dielectric layer 105, and the conductive layer 103 in the array region AR, the staircase region SR and the edge region ER as shown in FIG. 6E. Another first slit part P12 of the first slits SLT1 is disposed in a periphery of the staircase structure SC and extends through the dielectric layer 105 and the conductive layer 103 in the edge region ER as shown in FIG. 6F.

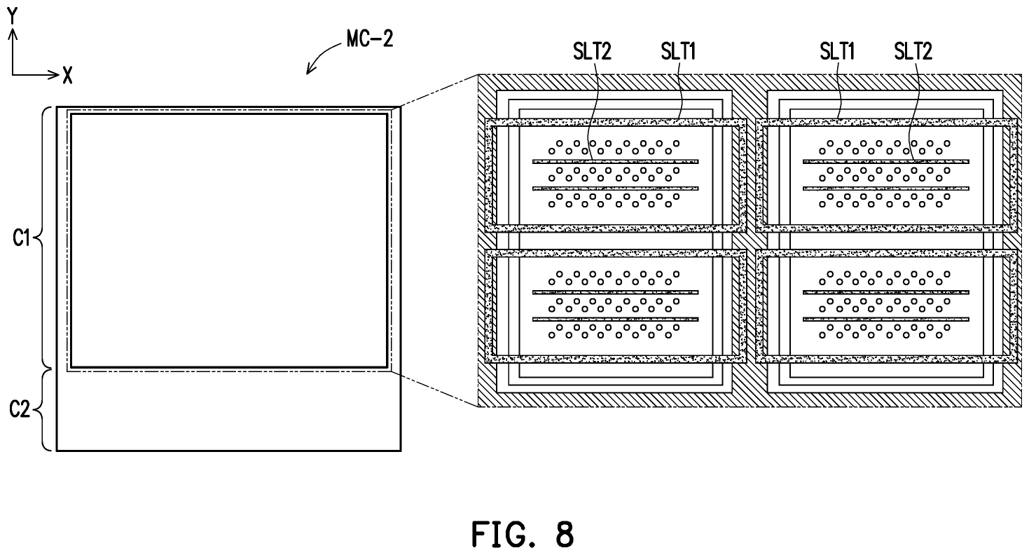

The present disclosure may be used in the 3D AND flash memory as well as the 3D NOR flash memory and the 3D NAND flash memory. The structure of the 3D NOR flash memory may be as shown in FIG. 2A. The chip MC-2 of 3D NAND flash memory may be as shown in FIG. 8.

Based on the above, in the embodiment of the present disclosure, the conductive layer located below the stack structure is patterned while a slit trench is formed. Therefore, the conductive layer may be used as the conduction path for the charge during the dry etching (e.g., plasma etching) process for forming the channel opening. As a result, the are effect may be reduced, and various material layers and components on the substrate can be prevented from being damaged by plasma bombardment. Therefore, the yield of the process may be improved by using the method of the embodiments of the present disclosure.

What is claimed is:

1. A memory device, comprising:
a dielectric substrate;
a conductive layer, located on the dielectric substrate;
a gate stack structure, located on a first part of the conductive layer;
a dielectric layer located on the gate stack structure and a second part of the conductive layer;
a plurality of ring-shaped slits extending through the dielectric layer, the gate stack structure and the conductive layer to define a plurality of tiles;
a plurality of inner slits arranged in each of the ring-shaped slits, wherein the plurality of inner slits defines a plurality of blocks in each tile,
wherein a height of the plurality of inner slits is the same as a height of the plurality of ring-shaped slits.

2. The memory device according to claim 1, wherein the plurality of ring-shaped slits are arranged in an array.

3. The memory device described in claim 1, further comprising:
at least a dummy slit arranged between adjacent two ring-shaped slits.

4. The memory device according to claim 1, wherein the height of the inner slit and the plurality of ring-shaped slit is greater than the height of the conductive layer and greater than the height of the gate stack structure.

5. A memory device, comprising:
a substrate including an array region, a staircase region, and an edge region, wherein the edge region surrounds the staircase region, and the staircase region surrounds the array region;
an interconnect structure, located on the substrate in the array region and the staircase region;
a conductive layer located on the interconnect structure in the array region, the staircase region and the edge region;
a gate stack structure located on the conductive layer in the array region and the staircase region, wherein the gate stack structure in the staircase region has a staircase structure;
a dielectric layer located on the conductive layer in the edge region and the step structure in the staircase region; and
a slit structure extending through the gate stack structure in the array region and the staircase region, the staircase structure, and the conductive layer to define a tile and to form a plurality of block in the tile.

6. The memory device according to claim 5, wherein sidewalls of the slit structure are in contact with sidewalls of the conductive layer and the dielectric layer.

7. The memory device according to claim 5, wherein the slit structure comprises:
an outer slit extending through the gate stack structure and the conductive layer in the array region and the staircase region to define the tile; and
a plurality of inner slits arranged in the outer slit, and extending in a first direction and passing through the gate stack structure and the conductive layer in the array region to define the plurality of blocks.

8. The memory device according to claim 5, wherein the outer slit includes:
a plurality of first slit parts extending in the first direction, wherein at least one of the plurality of first slit parts pass through the gate stack structure, the dielectric layer, and the conductive layer in the array region, the staircase region and the edge region; and
a plurality of second slit parts extending in a second direction and pass through the dielectric layer and the conductive layer in the edge region.

9. The memory device according to claim 8, wherein each of the plurality of first slit parts passes through the gate stack structure, the dielectric layer, and the conductive layer in the array region, the staircase region and the edge region.

10. The memory device according to claim 8, wherein other one of the plurality of first slit parts disposed in a periphery of the staircase structure and extends through the dielectric layer and the conductive layer in the edge region.

11. The memory device described in claim 5, further comprising:
at lease a dummy slit extending in the second direction, arranged beside the second slit part and extending through the dielectric layer and the conductive layer in the edge region.

12. A method for manufacturing a memory device, comprising:
providing a dielectric substrate;
forming a blanket conductive layer to cover the dielectric substrate;
forming a gate stack structure on the blanket conductive layer;
forming a plurality of channel openings in the gate stack structure, wherein the plurality of channel openings expose the blanket conductive layer;
forming a channel pillar in each channel opening;
forming a charge storage structure between the channel pillar and a plurality of gate conductive layers of the gate stack structure;
forming a dielectric layer on the gate stack structure and the blanket conductive layer; and
forming a plurality of slit structures extending through the dielectric layer, the gate stack structure, and the blanket conductive layer to define a plurality of tiles, and to define a plurality of blocks in each tile.

13. The method for manufacturing a memory device according to claim 12, wherein forming the plurality of slit structures comprises:
forming a plurality of first slits extending through the dielectric layer, the gate stack structure, and the blanket conductive layer to define the plurality of tiles; and
forming a plurality of second slits extending through the dielectric layer, the gate stack structure, and the blanket conductive layer, so as to define the plurality of blocks in each tile.

14. The method for manufacturing a memory device according to claim 13, wherein forming the plurality of slit structures comprises:
forming a plurality of first slit trenches and a plurality of second slit trenches extending through the dielectric layer, the gate stack structure, and the blanket conductive layer; and
filling an insulating material in the plurality of first slit trenches and the plurality of second slit trenches.

15. The method for manufacturing a memory device according to claim 14, wherein the insulating material fills up the plurality of first slit trenches and the plurality of second slit trench.

16. The method for manufacturing a memory device according to claim 14, wherein the insulating material does not fill the plurality of first slit trenches and the plurality of second slit trenches, and has an air gap located in the insulating material.

17. The method of manufacturing a memory device as described in claim 14, wherein the insulating material comprises a liner layer, covering sidewalls of the plurality of first slit trenches and the plurality of second slit trenches, and forming the plurality of slit structures further comprises forming a conductive material in a space between the liner layer.

18. The method for manufacturing a memory device according to claim 12, wherein the method for forming the plurality of channel openings comprises performing a plasma etching, and the blanket conductive layer is used as a discharge path.
